(19) United States
(12) Patent Application Publication
(10) Pub. No.: US 2009/0036313 A1
(43) Pub. Date: Feb. 5, 2009

(54) Coated superconducting materials

(76) Inventors: Liliana Stan, Los Alamos, NM (US); Igor Olegovich Usov, Los Alamos, NM (US); Quanxi Jia, Los Alamos, NM (US); Raymond F. DePaula, Santa Fe, NM (US)

Correspondence Address: LOS ALAMOS NATIONAL SECURITY, LLC, LOS ALAMOS NATIONAL LABORATORY, PPO. BOX 1663, LC/IP, MS A187, LOS ALAMOS, NM, 87545, US

(21) Appl. No.: 12/220,932

(22) Filed: Jul. 29, 2008

Related U.S. Application Data
(60) Provisional application No. 60/965,692, filed on Jul. 30, 2007.

(51) Int. Cl. H01L 39/12

(52) U.S. Cl. 505/238; 428/457

(57) ABSTRACT

A superconducting article comprising a substrate and a single composite layer deposited onto said substrate, wherein said single composite layer comprises Y₂O₃ and Al₂O₃, has a thickness of from about 20 nm to about 700 nm, and wherein the ratio of aluminum to yttrium is from about 10:1 to about 1:10; and wherein said superconducting article has a critical current density of at least 1 MA/cm².

### RELATED APPLICATIONS

This application claims the benefit of U.S. Provisional Application No. 60/965,692 filed on Jul. 30, 2007.

### STATEMENT OF FEDERAL RIGHTS

The United States government has rights in this invention pursuant to Contract No. DE-AC52-06NA25396 between the United States Department of Energy and Los Alamos National Security, LLC for the operation of Los Alamos National Laboratory.

### FIELD OF THE INVENTION

The present invention relates to superconductor materials comprising a combined nucleation layer and diffusion barrier layer.

### BACKGROUND OF THE INVENTION

Conductors having a thick superconducting film deposited on a substrate have commercial applications for transmission cables, motors and other electrical power components. The preparation of composite structures suitable for subsequent deposition of a thick film coating is critical to a number of technical areas. For example, composite structures with a thick film include ferroelectric structures, photovoltaic structures, and superconducting structures. If the ultimate structure is used as a superconducting structure, then the thick film may include a metal substrate and a high temperature superconductor (“HTS”), for example, yttrium barium copper oxide (YBCO). Between the metal substrate and the HTS, it is necessary to have one or more non-superconducting materials, including one or more barrier layers, buffer layers, and/or templates. A composite structure coated with an HTS thick film and the requisite additional layers is commonly referred to as a “coated conductor” or “coated superconductor.”

One technique used to fabricate coated conductors is ion beam assisted deposition (IBAD). When IBAD is used, a coated conductor may comprise the following layers: (1) a polycrystalline substrate; (2) a barrier layer (for example, Al₂O₃); (3) a nucleation layer (for example, Y₂O₃); (4) a homoepitaxial-MgO/IBAD-MgO layer; (5) and a buffer layer (for example, LaMnO₃ or SrTiO₃), on top of which the HTS may be deposited. It has long been thought that these four layers between the substrate and the HTS are necessary to produce a high quality superconducting material, as each layer in this standard construction of the coated conductor provides its own functionality. The Al₂O₃ serves as a barrier layer to prevent inter-diffusion between the substrate and the subsequent layers. The Y₂O₃ serves as a nucleation layer for the growth of high quality biaxially aligned IBAD-MgO. The IBAD-MgO and the homoepitaxial MgO serve as a template to grow a biaxially oriented buffer layer and HTS thick film. The LaMnO₃, SrRuO₃, SrTiO₃, or mixtures of SrRuO₃ and SrTiO₃ serve as a buffer layer to enhance the high quality epitaxial growth of the HTS thick film. The process which is required to produce these complex, multi-layered structures is both costly and lengthy. A need exists, therefore, to produce coated conductors with similarly high critical current densities (J_{c}) in a more cost-efficient and time-efficient manner.

### SUMMARY OF THE INVENTION

The present invention meets the aforementioned need by providing a coated superconductor having a high J_{c} wherein the nucleation layer and the diffusion barrier layer are combined into a single nucleation layer and diffusion barrier layer (hereinafter referred to as a “single composite layer,” or “composite layer”) This is contrary to the long accepted model requiring two separate layers (see, e.g., U.S. Pat. No. 6,921,741, Jia et al.) and to previous work which had shown that removal of either the nucleation layer or the diffusion barrier layer results in poorer performance of the superconducting material (i.e., a lower J_{c}) In addition, it was believed that it would not be possible to create a single layer that could fulfill both of the very dissimilar functions of the nucleation layer and the diffusion barrier layer, and that the application of the superconducting layer under high temperature conditions would lead to undesirable chemical reactions. For example, combination of Y₂O₃ and Al₂O₃ at high temperatures would be expected to form chemical species such as Y₃Al₅O₁₂, YAlO₃, Al₂Y₄O₉, Y₃Al₅O₁₂, YAlO₃, and/or Al₂Y₄O₉. In addition, it was thought that at high temperatures, the materials of the nucleation layer and the diffusion barrier layer would form a porous polycrystalline (or “rock-like”) structure, which would function poorly as a barrier. Surprisingly, however, it has been found that undesirable chemical reactions occur minimally or not at all, and that the composite layer materials form an amorphous structure having excellent barrier properties. Combination of the nucleation layer and the diffusion barrier layer additionally saves time and effort in a process which is lengthy, complex, and must be performed to strict specifications.

The following describe some non-limiting embodiments of the present invention.

According to a first embodiment of the present invention, a superconducting article is provided comprising a substrate and a single composite layer deposited onto said substrate, wherein said single composite layer comprises Y₂O₃ and Al₂O₃, has a thickness of from about 20 nm to about 700 nm, and wherein the ratio of Al₂O₃ to Y₂O₃ is from about 10:1 to about 1:10; and wherein said superconducting article has a critical current density of at least 1.0 MA/cm².

According to another embodiment of the present invention, a superconducting article is provided comprising a substrate; a single composite layer comprising yttrium and aluminum deposited onto the substrate, wherein the single composite layer is suitable for the growth of a biaxially aligned cubic oxide and substantially prevents diffusion of a substrate component to subsequently deposited layers; a homoepitaxial-oxide/IBAD-deposited oxide layer deposited onto the single composite layer; a buffer layer deposited onto the homoepitaxial-oxide/IBAD-deposited oxide layer; and a high temperature superconducting layer deposited onto the buffer layer.

### BRIEF DESCRIPTION OF THE DRAWINGS

FIG. 1(a) shows the coated superconductor of the present invention comprising a single composite layer. FIG. 1(b) shows a traditional configuration of a coated superconductor having a separate diffusion barrier layer and a nucleation layer.

FIG. 2 shows the x-ray diffraction (“XRD”) rocking curve on the (002) reflection of MgO on a coated superconductor comprising a single composite layer.

FIG. 3 shows the XRD⁻ Φ-scan of the (202) reflection of MgO on a coated superconductor comprising a single composite layer.

FIG. 4 shows the XRD 2η-scan of the YBCO film on a coated superconductor comprising a single composite layer.

FIG. 5 shows the XRD rocking curve on the (005) reflection of an YBCO film deposited on a coated superconductor comprising a single composite layer.

FIG. 6 shows the XRD Φ-scan of the (005) reflection of an YBCO film deposited on a coated superconductor comprising a single composite layer.

FIG. 7 shows the critical current density of an YBCO film deposited on a coated superconductor comprising a single composite layer.

### DETAILED DESCRIPTION OF THE INVENTION

In all embodiments of the present invention, all percentages are by weight of the total composition, unless specifically stated otherwise. All ranges are inclusive and combinable. All numerical amounts are understood to be modified by the word “about” unless otherwise specifically indicated.

“Coated superconductor,” as used herein, refers to flexible composite structures comprising a high temperature superconducting layer.

“Critical current density,” as used herein, means the critical current density as measured by a standard four point measurement, as would be understood by one of skill in the art and are understood to be performed at the temperature of liquid nitrogen, or 77K (adjusted appropriately for altitude).

“FWHM,” as used herein, means full width at half maximum of a given peak, or maxima.

“Suitable for the growth of a biaxially aligned cubic oxide,” as used herein, means that a coated superconductor comprising the biaxially aligned cubic oxide has a critical current density of at least 1.0 MA/cm².

### Substrate

The present invention comprises a substrate (or “base substrate”). The substrate comprises one or more materials onto which a single composite layer may be stably deposited. Some non-limiting examples of suitable substrate materials include polycrystalline metals, polycrystalline ceramics, single crystals, amorphous materials, and combinations thereof. Non-limiting examples of polycrystalline metals include nickel-based alloys such as Hastelloy™ metals, Haynes™ metals and Inconel™ metals; iron-based metals such as steels and stainless steels; copper-based metals such as copper-beryllium alloys, and combinations thereof. Non-limiting examples of suitable polycrystalline ceramics include polycrystalline aluminum oxide, polycrystalline yttria-stabilized zirconia (“YSZ”), forsterite, yttrium-iron-gamet (“YIG”), silica, and combinations thereof. Non-limiting examples of suitable single crystals include magnesium oxide, lanthanum aluminate, aluminum oxide, and combinations thereof. Non-limiting examples of suitable amorphous materials include silica, metallic glass, glass, and combinations thereof. The choice of substrate is determined by the composite structure's ultimate application. For example, if it is necessary for the final product to be shaped into coils, motors, magnets and the like, then the substrate preferably comprises a polycrystalline metal. In one embodiment, the substrate comprises at least one polycrystalline metal, and alternatively, a single type of polycrystalline metal.

The thickness of the substrate may vary considerably, depending upon the intended application of the final product. In one embodiment, the substrate may have a thickness of from about 25 μm (micrometers) to about 1 mm, and alternatively has a thickness of from about 25 μm to about 75 μm.

The substrate may be mechanically polished, electrochemically polished or chemically mechanically polished to provide a smoother surface. Additionally or alternatively, the desired smoothness for subsequent depositions can be provided by the first coating layer, i.e., an inert oxide material layer. By “inert” is meant that this oxide material does not react chemically with the base substrate or with any subsequently deposited materials. Examples of suitable inert oxide materials include materials other than erbium oxide, such as aluminum oxide, yttrium oxide, and yttria-stabilized zirconia (YSZ). The inert oxide layer can be deposited on the base substrate by pulsed laser deposition, e-beam evaporation, sputtering or by any other suitable means. The layer is deposited at temperatures of generally greater than about 400.degree. C. When the base substrate is metallic, it often has a rough surface with, e.g., a RMS of 15 nm to 100 nm or greater. Generally, the inert oxide layer has a thickness of from about 100 nanometers (nm) to about 1000 nm depending upon the roughness of the base substrate with a thicker coating layer for rougher base substrate surfaces. The inert oxide layer serves to provide a smooth surface for subsequent depositions. By “smooth” is meant a surface having a root mean square (RMS) roughness of less than about 2 nm, preferably less than about 1 nm. To obtain the desired smoothness, it can be preferred to treat the deposited inert oxide layer by chemical mechanical polishing.

### Single Composite Layer

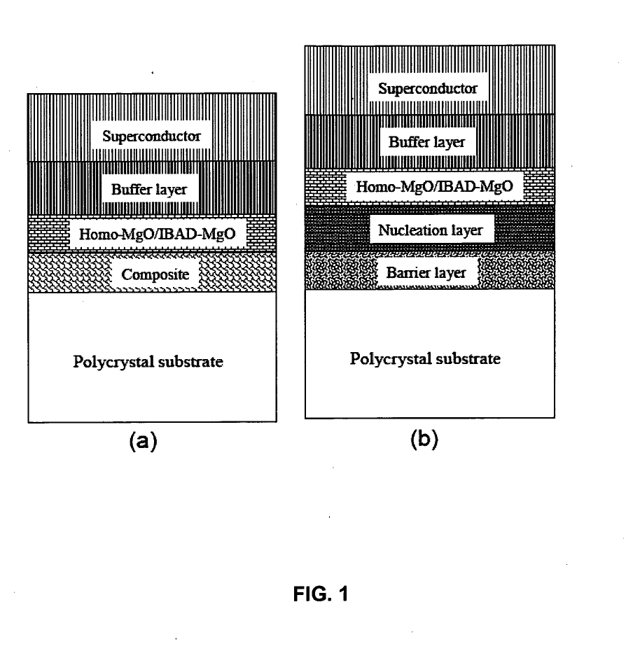

The present invention comprises a combined nucleation layer and diffusion barrier layer, herein referred to as a “single composite layer,” or “composite layer.” FIG. 1(a) depicts one embodiment of the present invention wherein the single composite layer is deposited onto the substrate. In contrast, FIG. 1(b) depicts a configuration of a superconductor material which comprises a separate nucleation layer and diffusion barrier layer. Therefore, the single composite layer serves a dual purpose, serving both as a nucleation layer for the growth of high quality biaxially aligned MgO and as a barrier layer to prevent the diffusion of components of the metal substrate to subsequently deposited layers.

The single composite layer comprises yttrium and aluminum. The yttrium and aluminum may be present in the form of nanocrystalline yttrium and nanocrystalline aluminum. In one embodiment, the single composite layer comprises Y₂O₃ and Al₂O₃, wherein the oxygen content in the oxides may or may not be present in a stoichiometric ratio. Alternatively, the single composite layer may consist essentially of Y₂O₃ and Al₂O₃.

The ratio of aluminum to yttrium may be from about 10:1 to about 1:10, alternatively is from about 10:1 to about 1:2, and alternatively is from about 1.75:0.25 to about 0.67:1.33.

The single composite layer may have an average thickness of from about 10 nm to about 100 nm, alternatively from about 50 nm to about 150 nm, alternatively from about 50 nm to about 100 nm, and alternatively from about 75 to about 100 nm.

### Homoepitaxial-Oxide/IBAD-Deposited Oxide Layer

The present invention may comprise one or more homoepitaxial-oxide/IBAD-deposited oxide layers. In one embodiment, the homoepitaxial-oxide/IBAD-deposited oxide layer is deposited onto the single composite layer. The homoepitaxial-oxide/IBAD-deposited oxide layer comprises a material suitable to serve as a template to grow a biaxially oriented HTS thick film, and may comprise an oxide with a cubic structure, fluorite structure, pervoskite structure, and/or an orthorhombic structure. Alternatively, the oriented material may comprise a nitride material, for example, titanium nitride. Non-limiting examples of suitable oxides include a cubic oxide with a rock-salt-like structure such as magnesium oxide, calcium oxide, strontium oxide, zirconium oxide, barium oxide, europium oxide, samarium oxide, and combinations thereof. Other suitable oxides are described in U.S. Pat. No. 6,190,752, issued to Do et al. One non-limiting example of a suitable fluorite structure is cerium oxide. Non-limiting examples of suitable perovskite structures include strontium ruthenate, lanthanum magnate, and combinations thereof. One non-limiting example of an orthorhombic structure is lanthanum aluminate. The IBAD (ion beam assisted deposition) layer preferably comprises a layer of an oriented cubic magnesium oxide having a rock-salt-like structure and is deposited by electron beam evaporation with an ion beam assisted deposition (IBAD). Thus, in one preferred embodiment, the homoepitaxial-oxide/EBAD-deposited oxide layer is a homoepitaxial-MgO/IBAD-deposited MgO layer. The MgO in the IBAD-MgO layer is typically evaporated from a crucible of magnesia. An ion-assisted, electron-beam evaporation system similar to that described by Wang et al., App. Phys. Lett., vol. 71, no. 20, pp. 2955-2957 (1997), can be used to deposit such a MgO film. Alternatively, a dual-ion-beam sputtering system similar to that described by Iijima et al., IEEE Trans. Appl. Super., vol. 3, no. 1, pp. 1510 (1993), can be used to deposit such a MgO film. The MgO layer deposited by the IBAD process is generally from about 50 angstroms to about 500 angstroms in thickness, alternatively is from about 225 angstroms to about 400 angstroms, and preferably from about 100 angstroms to about 200 angstroms.

After deposition of the oriented MgO material having a rock-salt-like structure, an additional thin homo-epitaxial layer of the MgO may be deposited by a process such as electron beam or magnetron sputter deposition. This thin homo-epitaxial layer can generally be about 50 angstroms to 1000 angstroms, prefereably 100 angstroms to 500 angstroms in thickness. Deposition of the homo-epitaxial layer by such a process can be more readily accomplished than depositing the entire thickness by ion beam assisted deposition.

### Buffer Layer

The present invention may comprise one or more buffer layers to serve as a substrate for a subsequently deposited high temperature superconducting (HTS) layer. In one embodiment, the buffer layer(s) are deposited onto the homoepitaxial-oxide/IBAD-deposited oxide layer. Thus, the buffer layer preferably has good structural and chemical compatibility between the MgO or other oriented cubic oxide material deposited in the IBAD process and subsequently deposited materials, e.g., YBCO. By “chemical compatibility” is meant that the intermediate (buffer) layer does not undergo property degrading chemical interactions, or has minimal interactions if at all, with the adjacent layers. By “structural compatibility” is meant that the intermediate (buffer) layer has a substantially similar lattice structure with the subsequently deposited material, e.g., superconductive material. Among the materials suitable as one or more intermediate (buffer) layers are cerium oxide, yttria-stabilized zirconia, strontium titanate (SrTiO₃), strontium ruthenate (SrRuO₃), mixtures of strontium titanate and strontium ruthenate (e.g., molar mixtures of Sr₁₋ₓRuₓTiO₃ where x may be about 0.5), lanthanum manganate (LaMnO₃), yttrium oxide, europium copper oxide (Eu₂CuO₄), neodymium copper oxide (Nd₂CuO4), yttrium copper oxide (Y₂CuO₄), and other rare earth copper oxides (RE₂CuO₄) or rare earth oxides and other cubic oxide materials such as those described in U.S. Pat. No. 5,262,394, by Wu et al. for “Superconductive Articles Including Cerium Oxide Layer.” Preferably, the buffer layer comprises strontium ruthenate, strontium titanate or a mixture thereof. The layer of strontium ruthenate and/or strontium titanate may be from about 200 angstroms to about 1500 angstroms in thickness, and preferably is from about 400 angstroms to about 600 angstroms in thickness. The buffer layer(s) are generally deposited at temperatures of greater than about 600° C., and preferably at temperatures of from about 600° C. to about 800° C.

### Superconducting Layer

The present invention may comprise a superconducting layer comprising superconductor materials, or alternatively may comprise photovoltaic materials, magnetic materials, ferroelectric materials, ferromagnetic materials, piezolelectirc materials, insulating materials, conductive materials, precursor materials for superconductors, and combinations thereof. In one embodiment, the superconducting layer is a high-temperature superconducting (“HTS”) material, and may comprise bismuth- and thalium-based superconductor materials, YBCO (e.g., YBa₂Cu₃O_{7-δ}, Y₂Ba₄Cu₇O₁₄₊ₓ, and/or YBa₂Cu₄O₈), and combinations thereof. Preferably the high-temperature superconducting material is YBa₂Cu₃O_{7-δ}. In one embodiment, the superconducting layer is an HTS material comprising YBCO, in which other rare earth metals, including scandium, lanthanum, cerium, praseodymium, neodymium, samarium, europium, gadolinium, terbium, dysprosium, holmium, erbium, thulium, ytterbium, and lutetium, may be substituted for at least a portion of the yttrium. The rare earth metal may comprise from about 1% to about 99% of the superconducting layer, alternatively from about 5% to about 75%, and alternatively from about 75% to about 99% of the layer.

The superconducting layer may comprise particulate materials to enhance flux pinning properties, as described in U.S. Patent Application 60/963,255 (Driscoll et al.) Non-limiting examples of suitable particulate materials include barium zirconate, yttrium barium zirconate, yttrium oxide, and combinations thereof. The particulate materials may have an average diameter of in the longest dimension of from about 5 nm to about 100 nm and may be present in amounts of from about 1% to about 20%.

The superconducting layer may have a critical current densities (J_{c}) of at least 1 MA (10⁶ amperes/square centimeter.

Multilayer architectures can be employed for the superconducting layer such as described in U.S. Pat. No. 6,383,989 by Jia et al., where individual layers of the superconducting material can be separated by a layer of an insulating material to obtain a greater total thickness of the superconducting layer with higher critical current values.

A high temperature superconducting (HTS) layer may be deposited, e.g., by pulsed laser deposition or by methods such as evaporation including co-evaporation, e-beam evaporation and activated reactive evaporation, sputtering including magnetron sputtering, ion beam sputtering and ion assisted sputtering, cathodic arc deposition, chemical vapor deposition, organometallic chemical vapor deposition, plasma enhanced chemical vapor deposition, molecular beam epitaxy, a sol-gel process, liquid phase epitaxy and the like.

### Deposition of Single Composite Layer and Superconducting Layer

The single composite layer and the superconducting layer may be deposited by a variety of means, including pulsed laser deposition (“PLD”), metalorganic chemical vapor deposition (“MOCVD”), evaporation (e.g., e-beam evaporation and activated reactive evaporation), sputtering (e.g., magnetron sputtering, ion beam sputtering, and ion assisted sputtering), cathodic arc deposition, chemical vapor deposition, plasma enhanced chemical vapor deposition, atomic layer deposition, molecular beam epitaxy, sol-gel processes, liquid phase epitaxy, and any combinations thereof. Which method is used for deposition of the superconducting layer may depend upon the rare earth metal composition of the cubic metal oxide material. For example, if the rare earth metal composition ranges from about 6 atomic percent to about 75 atomic percent, PLD may be preferred. But, if the rare earth metal composition ranges from about 75 atomic percent to about 99 atomic percent, MOCVD may be preferred. When the superconducting layer is deposited by PLD, then the target material is pressed under high pressure (e.g., generally above 1000 pounds per square inch) into a pellet or disk. A pressed pellet (i.e., target material pellet) is sintered in an approximately 950° C. oxygen or oxygen-containing atmosphere for at least one hour, and preferably from about 12 hours to about 24 hours. One example of a suitable PLD apparatus is shown by Muenchausen et al., “Effects of Beam Parameters on Excimer Laser Deposition of YBa₂Cu₃O_{7-δ},” Appl. Phys. Lett. 56, 578 (1990).

The substrate upon which the target material is to be deposited is mounted upon a heated holder in the deposition chamber. The heated holder maintains a temperature during deposition from about 600° C. to about 950° C. (preferably from about 700° C. to about 850° C.) and rotates at about 0.5 rotations per minute (to achieve uniform deposition).

The pressed pellet is placed in the deposition chamber. A laser, for example an excimer laser (20 nanoseconds, 248 or 308 nanometers) targets the pressed pellet at an incident angle of about 45°. The distance between the material upon which the target material is to be deposited and the pressed pellet is from about 4 centimeters to about 10 centimeters. The deposition chamber is maintained at a pressure from about 0.1 millitorr to about 10 Torr, and preferably from about 100 millitorr to about 250 millitorr.

The deposition rate of the target material varies from about 0.1 angstrom per second to about 200 angstrom per second by changing the laser repetition rate from about 0.1 Hz to about 200 Hz. The laser beam dimensions are about 1 mm by about 4 mm with an average energy density from about 1 J/cm² to about 4 J/cm². After the target material is deposited, it is cooled to room temperature in a high partial pressure of oxygen (greater than about 100 Torr).

If the superconducting film is deposited by MOCVD, then the target material is dissolved and forms a liquid precursor solution. The liquid precursor solution is pumped at a constant rate of from about 0.1 milliliters per minute to about 10 milliliters per minute into a vaporizer maintained at a steady temperature ranging from about 180° C. to about 300° C. and a steady pressure ranging from about 1 Torr to about 15 Torr. An inert gas (e.g., argon, nitrogen, etc) may be supplied to the vaporizer at a rate of from about 500 ml per minute to about 4000 ml per minute. The material upon which the target material (i.e., vaporized precursor) is to be deposited is heated to a temperature from about 750° C. to about 850° C. in the deposition chamber. The vaporized precursor exits the vaporizer, is mixed with oxygen, and is transported to a deposition chamber through small-bore tubing. The small-bore tubing is maintained at a temperature from about 230° C. to about 270° C.

In the deposition chamber, the vaporized precursor is injected uniformly over the material upon which the target material (i.e., the vaporized precursor) is to be deposited through a showerhead (e.g., disc with perforated holes that achieve uniform flow). The distance between the material upon which the target material (i.e., the vaporized precursor) is to be deposited and the showerhead is from about.15 mm to about 30 mm. Moreover, the deposition chamber is maintained at a pressure from about 1 Torr to about 2.5 Torr, however, pressures may range up to about 500 Torr. After the target material is deposited, it is cooled to room temperature in a high partial pressure of oxygen (e.g., 100 Torr to about 760 Torr). Selvamanickam et al. (U.S. Patent Application 2004/0265649) and Selvamanickam et al. (U.S. Patent 2006/0115580) describe a suitable MOCVD process.

### EXAMPLES

The following represent illustrative, non-limiting examples of the present invention. One of skill in the art will understand that numerous modifications and variations will be apparent within the intended scope of the claimed invention.

### Example 1

The Y₂O₃—Al₂O₃ single composite layers were grown on an electropolished Ni-alloy at room temperature using reactive ion beam sputtering. The oxygen partial pressure was 3×10⁻⁵ Torr during the sputtering. A 900 eV Ar⁺ beam was applied to the target at an angle of 45°. The target was comprised of two pieces of metal: Al and Y with purity of 99.9% for both metals. The composition of the Y₂O₃—Al₂O₃ composite may be varied in two ways: by either changing the ratio of surface area of the two metal pieces or by setting the samples in different positions along the deposition zone. Both of these methods were used when producing the samples described in Table 1. The distance between the target and the substrates was 40 cm. The deposition rate was between 0.8 and 1.25 angstroms/s. The ratio of Y/Al of Y₂O₃—Al₂O₃ films was determined by Rutherford backscattering spectrometry (RBS). For RBS measurements, graphite substrates were used and placed next to the metal substrates during the deposition. The use of low atomic number substrate (such as graphite) is preferred for this technique as it allows for a more accurate measurement.

An MgO template layer was grown at ambient temperature using IBAD by evaporation of MgO and simultaneous ion bombardment. An electron beam gun provided the MgO vapors. Ion bombardment during the MgO growth was performed with 750 eV Ar⁺ ions at 45° incidence angle. The IBAD-MgO films were grown at a net deposition rate (MgO deposition rate minus the etching rate due to the assist ion bombardment) of about 0.5 angstrom/s to a total thickness of 10 nm. During the IBAD-MgO deposition, the evolution of texture was qualitatively monitored in situ with reflected high-energy electron diffraction (RHEED). The deposition was stopped when the intensity of the monitored diffraction spots leveled off. This condition was realized at a film thickness of about 10 nm. The films were then transferred to an RF sputter deposition system where 100 nm homoepitaxial MgO layer was deposited at 600° C. This additional homoepitaxial layer was necessary to provide sufficient material for X-ray diffraction (XRD) analysis.

Table 1 summarizes Y₂O₃—Al₂O₃ single composite layer parameters (thickness and composition) and IBAD-MgO texture phi-scan and rocking curve.

TABLE 1

| | | | | | Rocking |
|---|---|---|---|---|---|
| | | | | □scan | curve |
| | Thickness | | | FWHM | FWHM |
| Run # | (nm) | Al/Y Ratio | MgO run # | (deg.) | (deg.) |
| YAlO1(4) | 125 | 1.76/0.24 | MYAlO2(4) | 6.5 | 3.2 |
| YAlO1(3) | 150 | 1.66/0.34 | MYAlO2(3) | 6.5 | 2.6 |
| YAlO1(2) | 115 | 1.46/0.54 | MYAlO2(2) | 7.1 | 3.5 |
| YAlO2(4) | 140 | 1.28/0.72 | MYAlO3(4) | 5.5 | 2.3 |
| YAlO1(1) | 105 | 1.24/0.76 | MYAlO2(1) | 6.0 | 2.4 |
| YAlO2(3) | 155 | 1.08/0.92 | MYAlO3(3) | 6.0 | 2.1 |
| YAlO2(2) | 120 | 0.81/1.19 | MYAlO3(2) | 6.0 | 1.7 |
| YAlO2(1) | 100 | 0.67/1.331 | MYAlO3(1) | 5.4 | 1.8 |

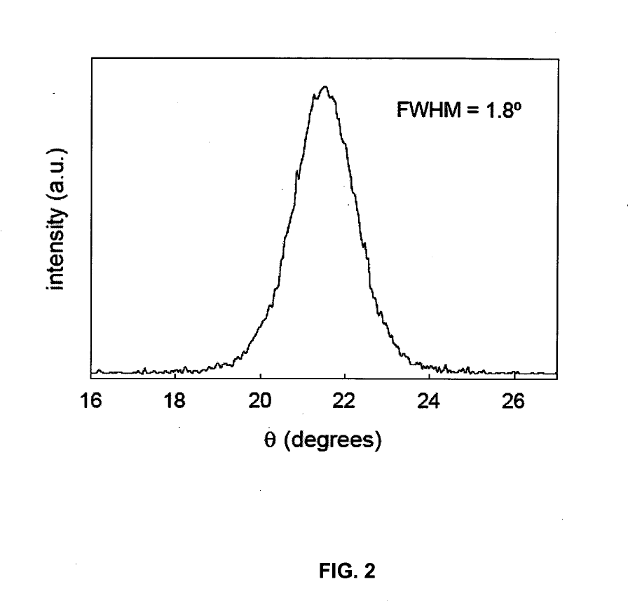

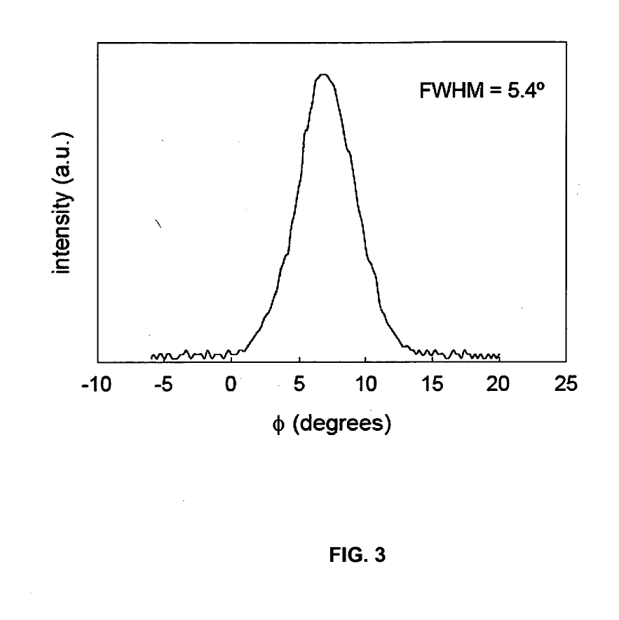

FIG. 2 and FIG. 3 depict the x-ray diffraction rocking curve on the (002) reflection of MgO and phi-scan of the (202) reflection of MgO using a single composite layer between the metal substrate and the IBAD-MgO.

### Example 2

Pulsed laser deposition (XeCl excimer laser with λ=308 nm) was used to deposit buffer layer SrTiO₃ (STO) on the IBAD layer of Example 1. The processing parameters for STO were initially optimized for coated conductors in order to get the best structural and superconductor properties. A substrate temperature of 775° C. and an oxygen pressure of 200 mTorr were used for the deposition. Following deposition, the films were cooled down to room temperature in an oxygen pressure of 300 Torr without any further thermal treatment. The STO was c-axis oriented as confirmed by the x-ray diffraction 2-theta-scan of the STO film on polycrystalline metal substrate using a single composite layer between the metal substrate and the MgO template. The x-ray diffraction phi-scan of (101) reflection of STO revealed a FWHM value in the range of 4.3-5.0 degrees.

### Example 3

Pulsed laser deposition (XeCl excimer laser with λ=308 nm) was used to deposit both buffer layer STO and superconducting layer YBCO on the substrate outlined in Example 1. The processing parameters for both STO and YBCO were initially optimized for coated conductors in order to get the best structural and superconductor properties. A substrate temperature of 775° C. and an oxygen pressure of 200 mTorr were used for the deposition of STO, but 765° C. and an oxygen pressure of 200 mTorr for the deposition of YBCO. The YBCO was deposited right after the STO deposition without breaking the vacuum. Following the YBCO deposition, the films were cooled down to room temperature in an oxygen pressure of 300 Torr without any further thermal treatment.

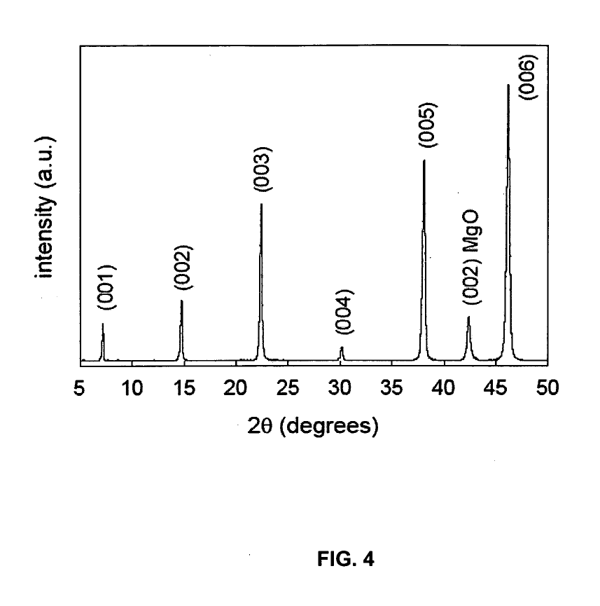

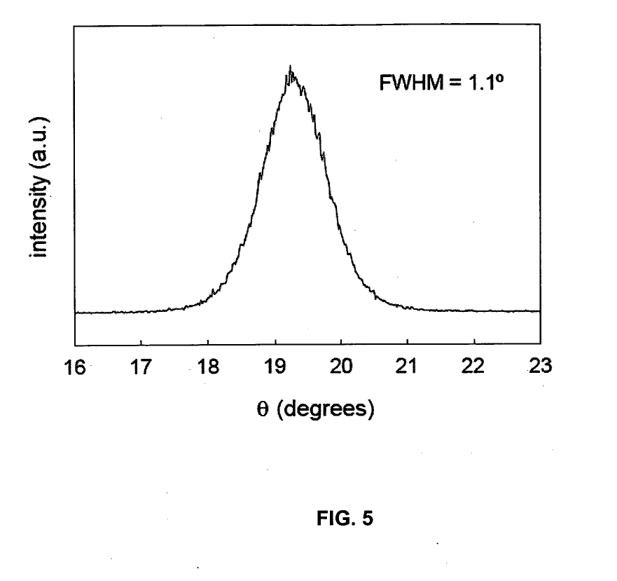

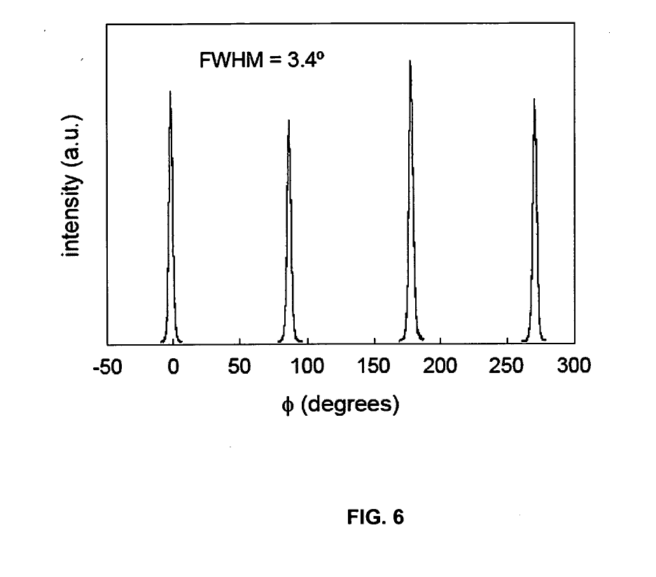

The YBCO (with a thickness of 0.5 micrometer) was c-axis oriented as confirmed by the x-ray diffraction 2-theta-scan of the YBCO film on polycrystalline metal substrate using a single composite layer between the metal substrate and the MgO template (shown in FIG. 4). The rocking curve of (005) reflection of YBCO was 1.1 degree (shown in FIG. 5). The x-ray diffraction phi-scan of (103) reflection of YBCO revealed a FWHM value of 3.4 degree (see FIG. 6).

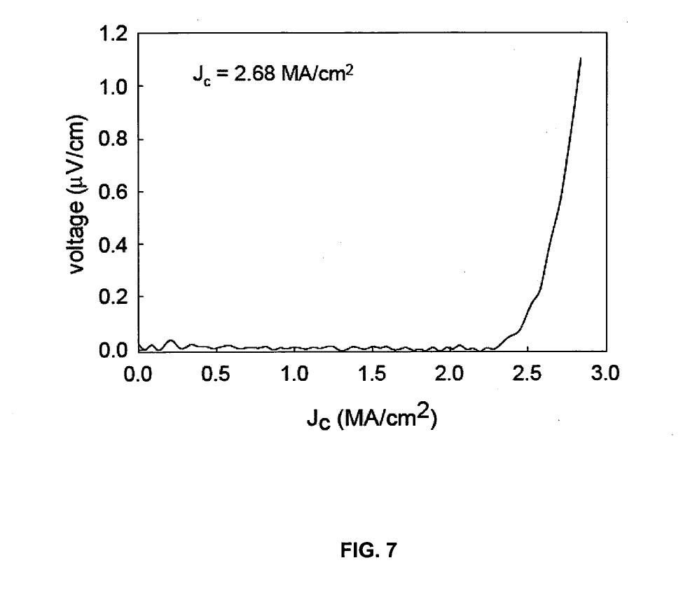

The YBCO film was patterned using a wet chemical etching method. The critical current density was measured by the standard four-point method at liquid nitrogen temperature (75.5 K at Los Alamos, N. Mex.) using the 1 microvolt/cm voltage criterion. The critical current density was 2.68 MA/cm² as shown in FIG. 7.

All documents cited in the Detailed Description of the Invention are, in relevant part, incorporated herein by reference; the citation of any document is not to be construed as an admission that it is prior art with respect to the present invention. To the extent that any meaning or definition of a term in this document conflicts with any meaning or definition of the same term in a document incorporated by reference, the meaning or definition assigned to that term in this document shall govern.

Whereas particular embodiments of the present invention have been illustrated and described, it would be obvious to those skilled in the art that various other changes and modifications can be made without departing from the spirit and scope of the invention. It is therefore intended to cover in the appended claims all such changes and modifications that are within the scope of this invention.

What is claimed is:

1. A superconducting article comprising:
a) a substrate;
b) a single composite layer deposited onto said substrate, wherein said single composite layer comprises Y₂O₃ and Al₂O₃, has a thickness of from about 20 nm to about 700 nm, and wherein the ratio of Al₂O₃ to Y₂O₃ is from about 10:1 to about 1:10; and wherein said superconducting article has a critical current density of at least 1 MA/cm².

2. The superconducting article of claim 1, wherein the single composite layer is suitable for the growth of biaxially aligned cubic oxide and substantially prevents diffusion of a substrate component to subsequently deposited layers.

3. The superconducting article of claim 1, wherein the substrate comprises a polycrystalline metal, a polycrystalline ceramic, a single crystal, an amorphous material, and combinations thereof.

4. The superconducting article of claim 3, wherein the substrate comprises a polycrystalline metal.

5. The superconducting article of claim 1, further comprising a homoepitaxial-oxide/IBAD-deposited oxide layer.

6. The superconducting article of claim 5, wherein said homoepitaxial-oxide/IBAD-deposited oxide layer is deposited onto the single composite layer.

7. The superconducting article of claim 1, further comprising a buffer layer.

8. The superconducting article of claim 7, wherein said buffer layer is deposited onto the homoepitaxial-oxide/IBAD-deposited oxide layer.

9. The superconducting article of claim 1, further comprising a high temperature superconducting layer.

10. The superconducting article of claim 9, wherein said high temperature superconducting layer is deposited onto the buffer layer.

11. The superconducting article of claim 7, wherein said high temperature superconducting layer comprises bismuth-based superconductor materials, thalium-based superconductor materials, YBCO, and combinations thereof.

12. The superconducting article of claim 8, wherein said high temperature superconducting layer comprises at least one rare earth metal.

13. A superconducting article comprising:
a) a substrate;
b) a single composite layer comprising yttrium and aluminum deposited onto the substrate, wherein the single composite layer is suitable for the growth of a biaxially aligned cubic oxide and substantially prevents diffusion of a substrate component to subsequently deposited layers;
c) a homoepitaxial-oxide/IBAD-deposited oxide layer deposited onto the single composite layer;
d) a buffer layer deposited onto the homoepitaxial-oxide/IBAD-deposited oxide layer; and
e) a high temperature superconducting layer deposited onto the buffer layer.

14. The superconducting article of claim 13, wherein the superconducting article has a critical current density of at least 1 MA/cm².

15. The superconducting article of claim 13, wherein the substrate comprises a polycrystalline metal.

16. The superconducting article of claim 13, wherein the single composite layer comprises Y₂O₃ and Al₂O₃.

17. The superconducting article of claim 16, wherein the ratio of Al₂O₃ to Y₂O₃ is from about 10:1 to about 1:10

18. The superconducting article of claim 13, wherein the homoepitaxial-oxide/IBAD-deposited oxide layer is a homoepitaxial-MgO/IBAD-deposited MgO layer.

19. The superconducting article of claim 13, wherein the buffer layer comprises strontium ruthenate.

20. The superconducting article of claim 13, wherein the high temperature superconducting layer comprises YBCO.
